(19) United States
(12) Patent Application Publication
(10) Pub. No.: US 2026/0104454 A1
(43) Pub. Date: Apr. 16, 2026

(54) SCAN TEST CIRCUIT

(71) Applicant: CANON KABUSHIKI KAISHA, Tokyo (JP)

(72) Inventor: KOICHI IWAO, Tokyo (JP)

(21) Appl. No.: 19/353,751

(22) Filed: Oct. 9, 2025

(30) Foreign Application Priority Data
Oct. 11, 2024 (JP) 2024-178727

(51) Int. Cl. G01R 31/3185

(52) U.S. Cl. CPC G01R 31/318536; G01R 31/318541; G01R 31/318544

(57) ABSTRACT

A scan test circuit includes a logic circuit and an analog circuit. The logic circuit includes a selection circuit and logic circuit blocks, each logic circuit block includes first to fourth flip-flops and first and second combinational circuits, the selection circuit is connected to the first and the third flip-flop, the first flip-flop is connected to the second flip-flop, the third flip-flop is connected to the fourth flip-flop, the second flip-flop is connected to the first combinational circuit, the first combinational circuit is connected to a third combinational circuit, the fourth flip-flop is connected to the second combinational circuit, the second combinational circuit is connected to a fourth combinational circuit, the third combinational circuit is connected to the fourth flip-flop, and the fourth combinational circuit is connected to the third flip-flop.

### BACKGROUND

### Field of the Technology

The present disclosure relates to a scan test circuit to be applied to a logic circuit configured to drive an analog circuit.

### Description of the Related Art

Generally, in the tests of semiconductor circuits, a logic circuit to be connected to an analog circuit, e.g., a vertical scanning circuit, is tested either on the analog circuit side, or using an observation flip-flop (hereinafter, abbreviated as FF) at the connection portion therebetween.

To perform a test on the side of the analog circuit, however, inspections need to be carried out using, for instance, a captured image of the circuit. Therefore, time and costs required in testing increase. Another alternative is to perform scan tests by implementing a scan test circuit in a part of the analog circuit. However, this alternative is incapable of inspecting the connection portion, hence a test coverage for assuring the quality of semiconductor circuits cannot be achieved.

Furthermore, in the inspection method using an observation FF, the scan chain becomes extended by the length of the observation FF. As a result, the time required in the shift operations of the scan tests becomes extended, hence the testing time increases. Moreover, the area of the circuit also increases, by the footprint occupied by the observation FF, hence the leakage power also increases accordingly.

Japanese Patent Laid-Open No. 2006-162490 discloses a technique for inspecting the connection portion between the analog circuit and the logic circuit. Japanese Patent Laid-Open No. H11-271401, Japanese Patent Laid-Open No. 2000-258506, and Japanese Patent Laid-Open No. 2021-143838 also disclose techniques for checking a part to be inspected.

However, even if the technique described in Japanese Patent Laid-Open No. 2006-162490 is used, the number of observation FFs used in the test is not reduced. Even with the use of the techniques described in Japanese Patent Laid-Open No. H11-271401, Japanese Patent Laid-Open No. 2000-258506, and Japanese Patent Laid-Open No. 2021-143838, not only there is not much freedom in the scan chain, but also the number of iterations of shift and capture operations in the scan test cannot be reduced. Therefore, none of the techniques are capable of reducing the time and the costs accrued in the testing.

### SUMMARY

The technique according to the present disclosure has been made with the foregoing in view, and the present disclosure provides a scan test circuit capable of reducing the time and costs accrued in testing.

According to some embodiments, a scan test circuit includes a logic circuit and an analog circuit, wherein the logic circuit includes a selection circuit and a plurality of logic circuit blocks to which a selection signal of the selection circuit is input, each of the plurality of logic circuit blocks includes a first flip-flop, a second flip-flop, a third flip-flop, a fourth flip-flop, a first combinational circuit, and a second combinational circuit, and is caused to operate in response to an input of the selection signal of the selection circuit, the selection circuit is connected to the first flip-flop and the third flip-flop, the first flip-flop is connected to the second flip-flop, the third flip-flop is connected to the fourth flip-flop, the second flip-flop is connected to the first combinational circuit, the first combinational circuit is connected to the analog circuit via a plurality of signal lines, the plurality of signal lines connected to the first combinational circuit are connected to a third combinational circuit, the fourth flip-flop is connected to the second combinational circuit, the second combinational circuit is connected to the analog circuit via a plurality of signal lines, the plurality of signal lines connected to the second combinational circuit are connected to a fourth combinational circuit, the third combinational circuit is connected to the fourth flip-flop, and the fourth combinational circuit is connected to the third flip-flop.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating a schematic configuration of a scan test circuit according to a first embodiment.

FIGS. 2A and 2B are diagrams schematically illustrating a general scan test circuit and operation timing thereof, respectively.

FIG. 3 is a circuit diagram illustrating an example of a configuration of a scan test circuit not using the technique according to the present disclosure.

FIG. 4 is a diagram of a circuit in which an observation FF is used in the scan test circuit without using the technique according to the present disclosure.

FIG. 5 is a diagram illustrating an example of a configuration of a scan test circuit according to a first embodiment.

FIG. 6 is a diagram illustrating an example of a configuration of a scan test circuit according to a second embodiment.

FIG. 7 is a diagram illustrating an example of a configuration of a scan test circuit according to a third embodiment.

FIG. 8 is a diagram illustrating an example of a configuration of a scan test circuit according to a fourth embodiment.

FIG. 9 is a schematic diagram of equipment including a semiconductor device according to a fifth embodiment.

### DESCRIPTION OF THE EMBODIMENTS

Embodiments of the present disclosure will now be described with reference to drawings. Note that the present disclosure is not limited to the following embodiments, and the following embodiments may be changed as appropriate within the scope not departing from the gist of the present disclosure. Further, in the drawings described below, those having the same function are given the same reference numerals and signs, and description thereof may be omitted or simplified.

### First Embodiment

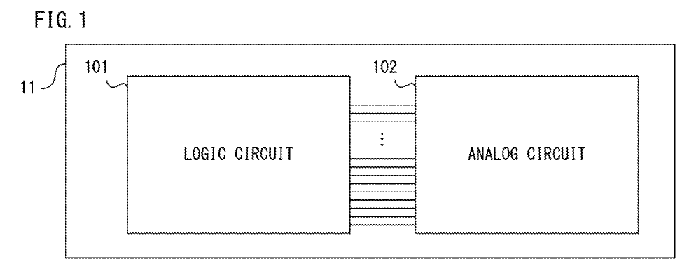

A semiconductor circuit according to a first embodiment will now be explained. FIG. 1 is a diagram illustrating a schematic configuration of a semiconductor circuit 11 that is a scan test circuit according to the first embodiment. Illustrated FIG. 1 is a logic circuit 101 having a large number of output signals and an analog circuit 102 receiving the output signals, in the semiconductor circuit. With such a circuit configuration, in order to address the challenge described above, it is necessary to develop a method for testing not only a combinational circuit and an output unit in the logic circuit 101 but also the analog circuit.

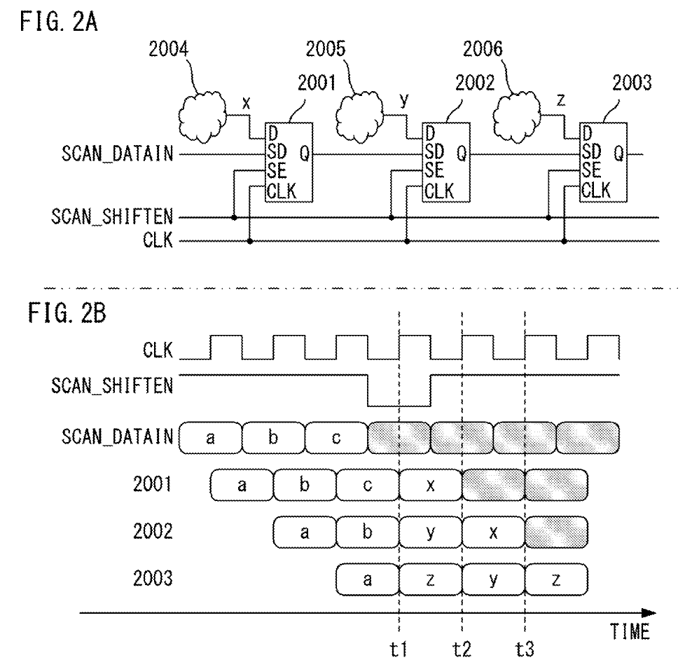

FIG. 2A and FIG. 2B illustrate, respectively, a schematic diagram of a circuit into which a general scan test is to be inserted, and the timings of operations. As illustrated in FIG. 2B, by being input with a clock from a clock CLK while a scan shift enable signal (SCAN_SHIFTEN) is high, data is transferred over a scan data-in signal (SCAN_DATAIN). While the scan shift enable signal (SCAN_SHIFTEN) is low, the data is input from the combinational circuit.

FIG. 2B is a waveform diagram generally illustrating the timings of operations in the circuit illustrated in FIG. 2A. As illustrated in FIG. 2B, at the time of a capture operation (time t1), data is transferred from each combinational circuit, with data x being transferred from a combinational circuit 2004 to an FF 2001; data y being transferred from a combinational circuit 2005 to an FF 2002; and data z being transferred from a combinational circuit 2006 to an FF 2003. At time t2 and time t3, the pieces of data having been transferred in response to the input of the clock CLK are output, so that that the output values from the combinational circuits can be inspected.

A configuration of the logic circuit relating to this embodiment will now be explained with reference to drawings. In the following description, the clock signal, the scan data-in signal, and the scan shift enable signal are omitted.

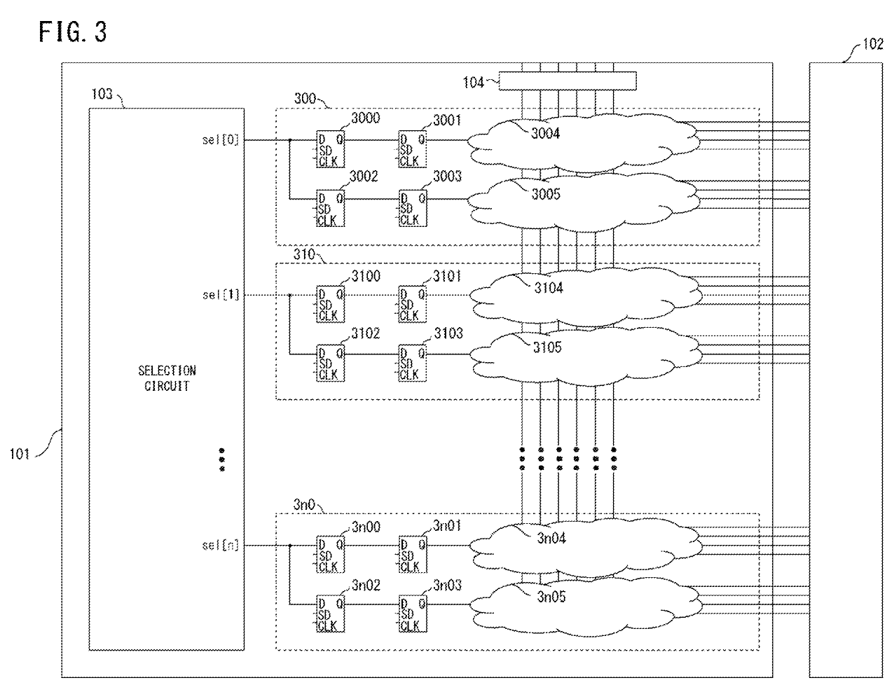

FIG. 3 illustrates a logic circuit configuration without the application of the embodiment. As illustrated in FIG. 3, the logic circuit 101 is provided with a selection circuit 103, block circuits 300, 310, ... 3n0 (where n is an integer of two or more; the same applies in the description hereinafter) caused to operate upon being selected, and an input signal control circuit 104 for combinational circuits.

The input signal control circuit 104 is connected to combinational circuits 3004, 3005, 3103, 3105, ... 3n04, and 3n05. The input signal control circuit 104 controls signals input to the combinational circuits 3004, 3005, 3103, 3105, ... 3n04, and 3n05. The block circuit 300 at least includes FFs 3000, 3001, 3002, and 3003, and the combinational circuits 3004 and 3005. In the same manner, the block circuit 310 at least includes FFs 3100, 3101, 3102, and 3103 and combinational circuits 3104 and 3105. In the same manner, the block circuit 3n0 at least includes FFs 3n00, 3n01, 3n02, and 3n03 and combinational circuits 3n04 and 3n05.

The selection circuit 103 is connected to the FFs 3000, 3002, 3100, 3102, ... 3n00, and 3n02. The FFs 3000, 3002, 3100, 3102... 3n00, and 3n02 are connected to the FFs 3001, 3003, 3101, 3103... 3n01, and 3n03, respectively.

The FF 3001 is connected to the combinational circuit 3004, and the FF 3003 is connected to the combinational circuit 3005. In the same manner, the FF 3101 is connected to the combinational circuit 3104, and the FF 3103 is connected to the combinational circuit 3105. In the same manner, the FF 3n01 is connected to the combinational circuit 3n04, and the FF 3n03 is connected to the combinational circuit 3n05.

With the block circuit illustrated in FIG. 3, although a scan test circuit can be implemented and scan tests can be performed, the combinational circuits 3004, 3005, 3104, 3105, ... 3n04, and 3n05 and output signals therefrom cannot be tested.

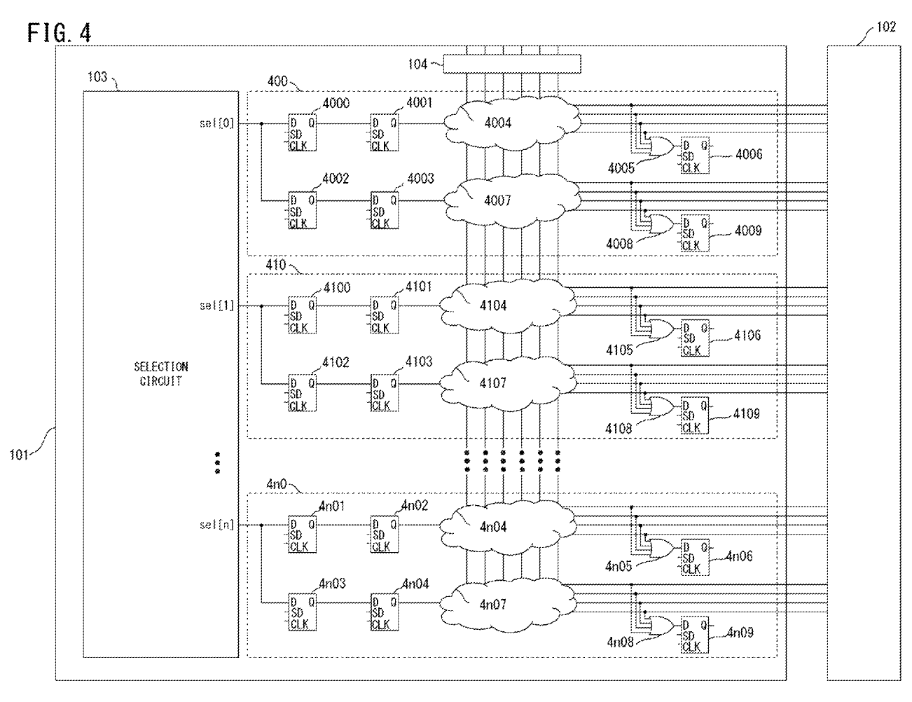

FIG. 4 illustrates an example of a circuit configuration using observation FFs, but without the application of the embodiment. As illustrated in FIG. 4, the logic circuit 101 includes the selection circuit 103, block circuits 400, 410, ... 4n0 caused to operate upon being selected by the selection circuit 103, and the input signal control circuit 104 for combinational circuits. The input signal control circuit 104 is connected to combinational circuits 4004, 4007, 4104, 4107, ... 4n04, and 4n07.

The selection circuit 103 is connected to FFs 4000 and 4002 in the block circuit 400, FFs 4100 and 4102 in the block circuit 410, ..., and FFs 4n00 and 4n02 in the block circuit 4n0.

The block circuit 400 at least includes the FFs 4000, 4001, 4002, and 4003, the combinational circuits 4004 and 4007, and includes logical ORs 4005 and 4008 and observation FFs 4006 and 4009 for scan testing. The FF 4000 is connected to the FF 4001, and the FF 4002 is connected to the FF 4003. The FF 4001 is connected to the combinational circuit 4004, and the FF 4003 is connected to the combinational circuit 4007.

Outputs from the combinational circuit 4004 are bundled by the logical OR 4005, and then output to the observation FF 4006. Outputs from the combinational circuit 4007 are bundled by the logical OR 4008, and then output to the observation FF 4009.

In FIG. 4, each of the block circuits 410 and 4n0 also has the same circuit configuration as that of the block circuit 400.

By implementing a scan test circuit and executing a scan test in the circuit illustrated in FIG. 4, it becomes possible to test the combinational circuits 4004, 4007, 4104, 4107, ... 4n04, 4n07 and the output signals from the combinational circuits.

However, with the observation FFs 4006, 4009, 4106, 4109 ... 4n06, and 4n09 provided, the circuit configuration illustrated in FIG. 4 has a larger number of observation FFs, so that the scan chain (a scan bus (a bus serially connecting the FFs)) becomes longer, and the testing time becomes extended by the increase in the number of observation FFs. As a result, the leakage power becomes increased accordingly.

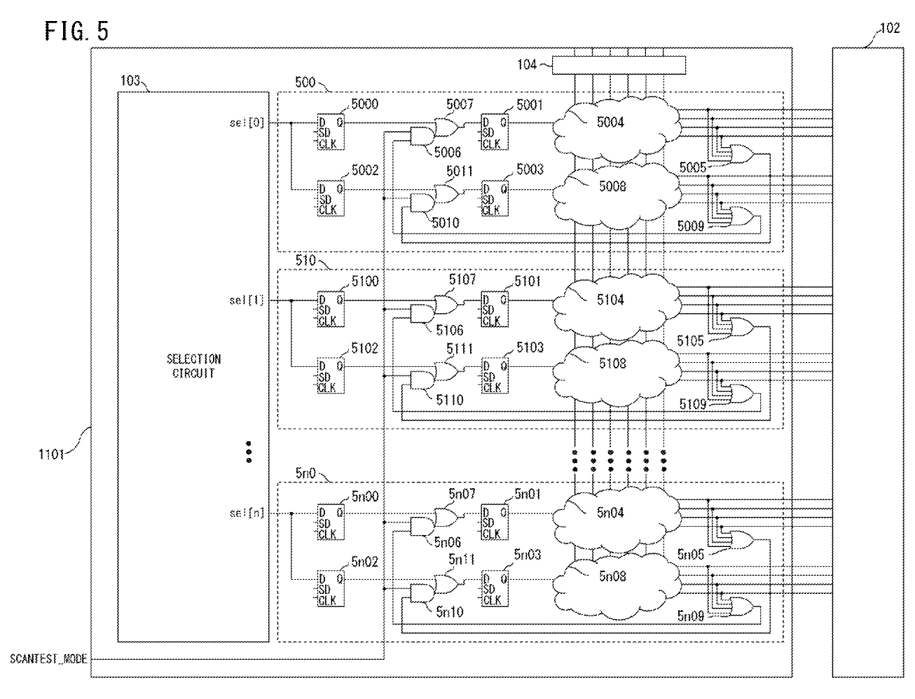

FIG. 5 illustrates an example of a schematic configuration of a logic circuit with the application of the embodiment. In the following description, configurations that are the same as those of the logic circuit 101 described above will be given the same reference numerals, and detailed description thereof will be omitted.

As illustrated in FIG. 5, a logic circuit 1101 includes the selection circuit 103, block circuits 500, 510 ... 5n0 caused to operate upon being selected by the selection circuit 103, and the input signal control circuit 104 for combinational circuits. The block circuits 500, 510 ... 5n0 are a plurality of logic circuit blocks to which the selection signal of the selection circuit is input. The block circuit 500 and the block circuit 510 correspond to a first logic circuit block and a second logic circuit block that are adjacent to each other, among the plurality of logic circuit blocks, respectively.

The input signal control circuit 104 is connected to combinational circuits 5004, 5008, 5104, 5108... 5n04, and 5n08. The selection circuit 103 is connected to FFs 5000 and 5002 in the block circuit 500, FFs 5100 and 5102 in the block circuit 510, ..., and FFs 5n00 and 5n02 in the block circuit 5n0.

The block circuit 500 includes the FFs 5000, 5001, 5002, and 5003, the combinational circuits 5004 and 5008, and combinational circuits 5005 and 5009 each being a logical OR for scan testing. The block circuit 500 also includes logical ANDs 5006 and 5010 and logical ORs 5007 and 5011. The FFs 5000, 5001, 5002, and 5003 herein correspond to first to fourth flip-flops, respectively. The combinational circuit 5004 corresponds to a first combinational circuit, and the combinational circuit 5008 corresponds to a second combinational circuit.

The combinational circuits 5004 and 5008 are connected to the analog circuit 102 via a plurality of signal lines. The semiconductor circuit 11 may be a vertical scanning circuit configured to scan a plurality of pixels arranged in a plurality of rows and a plurality of columns in a photoelectric conversion device, in units of one row, for example. In such a case, the analog circuit 102 may be a signal output unit (e.g., a buffer circuit) of the vertical scanning circuit. Another example of the semiconductor circuit 11 is a horizontal scanning circuit configured to scan a plurality of column circuits that are provided correspondingly to a plurality of respective columns of pixels in the photoelectric conversion device, in units of one column. In this case, the analog circuit 102 may be a signal output unit of the horizontal scanning circuit.

Each of the plurality of pixels of the photoelectric conversion device described herein includes a photoelectric converter that generates a signal charge on the basis of light being incident thereon, and outputs a signal having a signal level that is based on the signal charge, to the signal line. As the photoelectric converter, for example, a photodiode that accumulates signal charge over a certain period of time, an avalanche photodiode that causes avalanche multiplication in response to incidence of a photon, or a photoelectric conversion film including an organic film or an inorganic film may be used. Each of the vertical scanning circuit and the horizontal scanning circuit described herein may be configured as a decoder. In this configuration, the selection circuit 103 illustrated in FIG. 5 may be configured as an address decoder. In such a case, a signal generated by each of the combinational circuits 5n04 and 5n08 through reception of an output of the selection circuit 103, which is an address decoder, and an output of the input signal control circuit 104 is input to the analog circuit 102. On the basis of this input signal, the analog circuit 102 outputs a control signal to the outside of the analog circuit 102.

When the semiconductor circuit 11 is a vertical scanning circuit, this control signal is output as a signal for controlling each of the plurality of pixels. The signal for controlling a pixel may be, for example, a signal for controlling the transfer of charge at the photoelectric converter to another charge retaining unit, a signal for controlling the operation of resetting the charge retaining unit, and a signal for controlling a signal output from a pixel. When the semiconductor circuit 11 is a horizontal scanning circuit, the control signal is output as a signal for controlling each of the plurality of column circuits. The signal for controlling a column circuit may be, for example, a signal for controlling to read a signal generated by the column circuit, from the column circuit.

The plurality of signal lines connected to the combinational circuit 5004 are connected to the combinational circuit 5005, and the plurality of signal lines connected to the combinational circuit 5008 are connected to the combinational circuit 5009. The combinational circuit 5005 corresponds to a third combinational circuit, and the combinational circuit 5008 corresponds to a fourth combinational circuit.

The combinational circuits 5005 and 5009 do not need to be logical ORs, and may be logical XORs or the like. The output of the FF 5000 is input to one side of the 2-input logical OR 5007, and the output of the 2-input logical OR 5007 is input to the FF 5001. In the same manner, the output of the FF 5002 is input to one side of the 2-input logical OR 5011, and the output of the 2-input logical OR 5011 is input to the FF 5003.

A signal for a scan test mode is input to one sides of the inputs of the 2-input logical ANDs 5006 and 5010. The FF 5001 is connected to the combinational circuit 5004, and the FF 5003 is connected to the combinational circuit 5008.

The signals output from the combinational circuit 5004 are bundled by the combinational circuit 5005, and the resultant signal is input to the 2-input logical AND 5010. The output from the 2-input logical AND 5010 is then input to the 2-input logical OR 5011.

In the same manner, the signals output from the combinational circuit 5008 are bundled by the combinational circuit 5009, and the resultant signal is then input to the 2-input logical AND 5006. The output from the 2-input logical AND 5006 is then input to the 2-input logical OR 5007.

In the manner described above, the output from the FF 5001 is input to the FF 5003 via the combinational circuit. The output from the FF 5003 is input to the FF 5001 via the combinational circuit. Because the FFs outputting the data are different from the FFs receiving the input of data, the data is more likely to change. As a result, the efficiency of the scan test analysis in the logic circuit 1101 is improved, and the effect of reducing the testing time can be achieved.

Furthermore, according to this embodiment, it is not necessary to provide an additional observation FF in the logic circuit 1101, as in the logic circuit 101 described above. Therefore, the number of scan shifts is reduced, so that the time required in the test is reduced, and the concerns about an increase in the area by the footprint occupied by the observation FF and an increase in the leakage power are eliminated. The 2-input logical ANDs and the 2-input logical ORs in this embodiment may be other combinational circuits or complex gate circuits.

### Second Embodiment

A semiconductor device according to a second embodiment will now be explained. In the following description, configurations that are the same as those in the first embodiment will be given the same reference numerals, and detailed description thereof will be omitted.

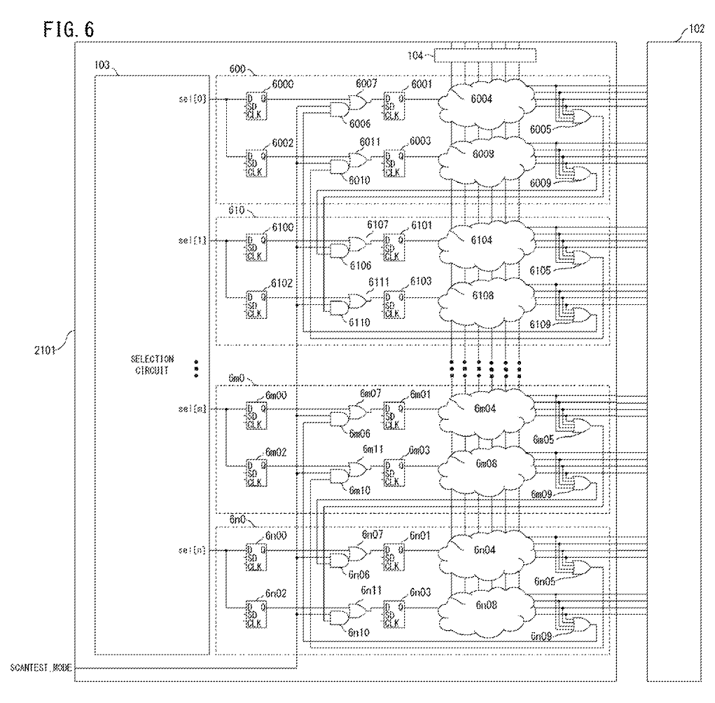

FIG. 6 illustrates an example of a schematic configuration of a logic circuit with the application of the embodiment. A logic circuit 2101 according to this embodiment is different from the logic circuit 1101 according to the first embodiment illustrated in FIG. 5 in that the outputs of the combinational circuits are connected across the block circuits. With the logic circuit 2101 according to this embodiment, because data is passed between the block circuits, the analysis efficiency in the scan test is further improved.

In this embodiment, the logic circuit 2101 includes the selection circuit 103, block circuits 600, 610 ... 6m0, and 6n0 caused to operate upon being selected by the selection circuit 103, and the input signal control circuit 104 for combinational circuits. The relationship between m and n herein is m=n-1.

The input signal control circuit 104 is connected to combinational circuits 6004, 6008, 6104, 6108 ... 6m04, 6m08, 6n04, and 6n08. The selection circuit 103 is connected to FFs 6000 and 6002 in the block circuit 600, FFs 6100 and 6102 in the block circuit 610, ..., FFs 6m00 and 6m02 in the block circuit 6m0, and FFs 6n00 and 6n02 in the block circuit 6n0.

The block circuit 600 includes the FFs 6000, 6001, 6002, 6003, the combinational circuits 6004 and 6008, and the combinational circuits 6005 and 6009 that are logical ORs for scan testing. The block circuit 600 also includes logical ANDs 6006 and 6010, and logical ORs 6007 and 6011. Note that, instead of ORs, XORs or the like may also be used for the combinational circuits 6005 and 6009.

The output from the FF 6000 is input to the 2-input logical OR 6007, and the output from the 2-input logical OR 6007 is input to the FF 6001. In the same manner, the output from the FF 6002 is input to the 2-input logical OR 6011, and the output from the 2-input logical OR 6011 is input to the FF 6003. A signal for the scan test mode is input to the 2-input logical ANDs 6006 and 6010. The FF 6001 is connected to the combinational circuit 6004, and the FF 6003 is connected to the combinational circuit 6008. The configuration described above is the same as that of the logic circuit 1101 according to the first embodiment illustrated in FIG. 5.

In this embodiment, however, the signals output from the combinational circuit 6004 are bundled by the combinational circuit 6005, and the resultant signal is then input to the 2-input logical AND 6110 belonging to another block circuit. The output from the 2-input logical AND 6110 is then input to the 2-input logical OR 6111. In the same manner, the signals output from the combinational circuit 6008 are bundled by the combinational circuit 6009, and the resultant signal is then input to the 2-input logical AND 6106 belonging to another block circuit. The output from the 2-input logical AND 6106 is then input to the 2-input logical OR 6107.

In the manner described above, in this embodiment, the output from the FF 6001 is input to the FF 6103 via the combinational circuit, and the output from the FF 6003 is input to the FF 6101 via the combinational circuit.

Because the FFs outputting the data are different from the FFs receiving the input of data, the data is more likely to change. As a result, the efficiency of the scan test analysis in the logic circuit 2101 is improved, and the effect of reducing the testing time can be achieved.

Furthermore, according to this embodiment, it is not necessary to provide an additional observation FF in the logic circuit 2101, as in the logic circuit 101 described above. Therefore, the number of scan shifts is reduced, so that the time required in the test is reduced, and the concerns about an increase in the area by the footprint occupied by the observation FF and an increase in the leakage power are eliminated. The 2-input logical ANDs and the 2-input logical ORs in this embodiment may be other combinational circuits or complex gate circuits.

### Third Embodiment

A semiconductor circuit according to a third embodiment will now be explained. In the following description, configurations that are the same as those in the first and the second embodiments will be given the same reference numerals, and detailed description thereof will be omitted.

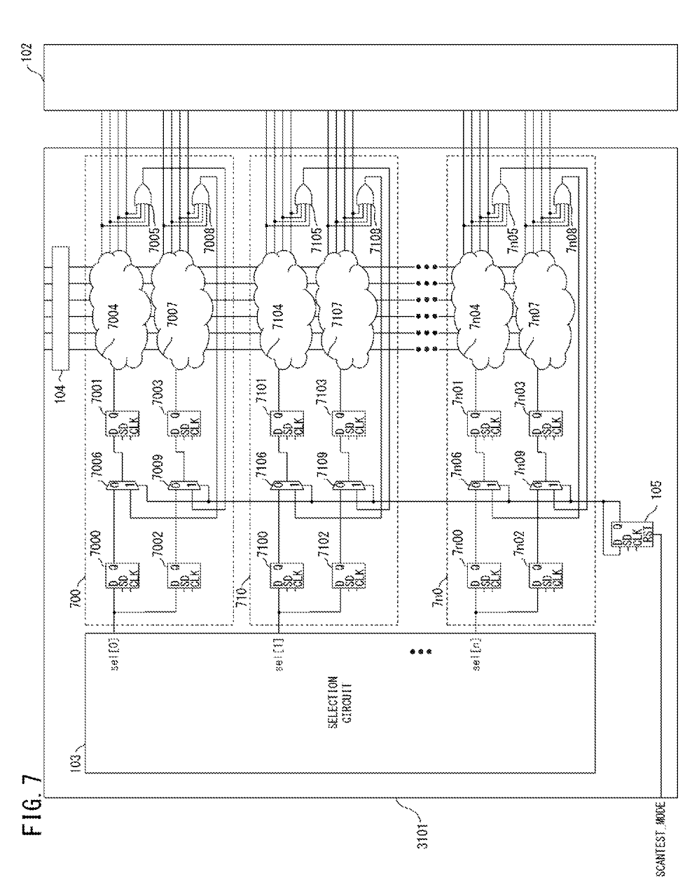

FIG. 7 illustrates an example of a schematic configuration of a logic circuit with the application of the embodiment. As illustrated in FIG. 7, the logic circuit 3101 includes the selection circuit 103, block circuits 700, 710 ... 7n0 caused to operate upon being selected by the selection circuit 103, and the input signal control circuit 104 for combinational circuits.

An FF 105 for switching multiplexers (hereinafter, abbreviated as Muxes) in the block circuits on the basis of a pattern is also provided for scan testing. The FF 105 uses a circuit configuration that, upon being input with a clock, retains the same value. The FF 105 keeps outputting 0 while SCANTEST_MODE is 0.

The selection circuit 103 is connected to FFs 7000 and 7002 in the block circuit 700, FFs 7100 and 7102 in the block circuit 710, ..., and FFs 7n00 and 7n02 in the block circuit 7n0. The block circuit 700 includes the FFs 7000, 7001, 7002, and 7003, combinational circuits 7004 and 7007, and combinational circuits 7005 and 7008 that are logical ORs for scan testing, and Muxes 7006 and 7009. The Mux 7006 corresponds to a first multiplexer to which the signal output from the fourth combinational circuit is input, and the output of which is input to a second flip-flop. The Mux 7009 corresponds to a second multiplexer to which the signal output from the third combinational circuit is input, and the output of which is input to the fourth flip-flop.

In this embodiment, instead of the logical ORs, logical XORs or the like may be used as combinational circuits 7005 and 7008. The output from the FF 7000 is input to a side of the Mux 7006, the side being a side where the selection signal is 0, and the output from the Mux 7006 is input to the FF 7001. In the same manner, the output from the FF 7002 is input to a side of the Mux 7009, the side being a side where the selection signal is 0, and the output from the Mux 7009 is input to the FF 7003.

An output from the FF 105 is also input to Muxes 7006 and 7009, as a selection signal for the Muxes 7006 and 7009. The FF 7001 is connected to the combinational circuit 7004, and the FF 7003 is connected to the combinational circuit 7007. The signals output from the combinational circuit 7004 are bundled by the combinational circuit 7005, and the resultant signal is then input to a side of the Mux 7009, the side being a side where the selection signal is 1. In the same manner, the signals output from the combinational circuit 7007 are bundled by the combinational circuit 7008, and the resultant signal is then input to a side of the Mux 7006, the side being a side where the selection signal is 1.

In this embodiment, as described above, the output from the FF 7001 is input to the FF 7003 via the combinational circuit, and the output from the FF 7003 is input to the FF 7001 via the combinational circuit.

Because the FFs outputting the data are different from the FFs receiving the input of data, the data is more likely to change. As a result, the efficiency of the scan test analysis in the logic circuit 3101 is improved, and the effect of reducing the testing time can be achieved.

Furthermore, according to this embodiment, it is not necessary to provide an additional observation FF in the logic circuit 3101, as in the logic circuit 101 described above. Therefore, the number of scan shifts is reduced, so that the time required in the test is reduced, and the concerns about an increase in the area by the footprint occupied by the observation FF and an increase in the leakage power are eliminated. In this embodiment, the Muxes may be other combinational circuits or complex gate circuits.

### Fourth Embodiment

A semiconductor circuit according to a fourth embodiment will now be explained. In the following description, configurations that are the same as those in the first to the third embodiments will be given the same reference numerals, and detailed description thereof will be omitted.

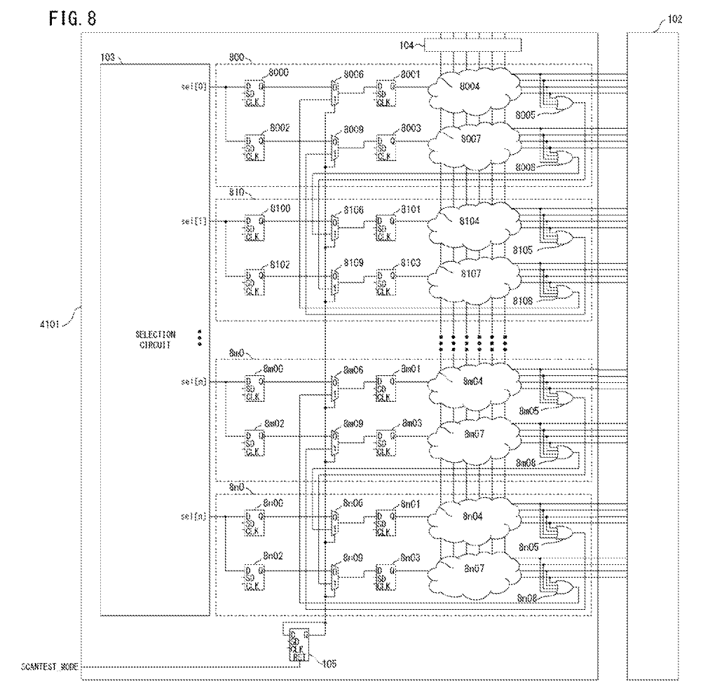

FIG. 8 illustrates an example of a schematic configuration of a logic circuit with the application of the embodiment. As illustrated in FIG. 8, this logic circuit 4101 includes the selection circuit 103, block circuits 800, 810 ... 8m0, 8n0 caused to operate upon being selected by the selection circuit 103, and the input signal control circuit 104 for combinational circuits. The relationship between m and n is m=n-1.

The FF 105 for switching the Muxes in the block circuits on the basis of patterns is also provided for scan testing. The FF 105 uses a circuit configuration that, upon being input with a clock, retains the same value. The FF 105 keeps outputting 0 while SCANTEST_MODE is 0.

The selection circuit 103 is connected to FFs 8000 and 8002 in the block circuit 800, FFs 8100 and 8102 in the block circuit 810, ..., FFs 8m00 and 8m02 in the block circuit 8m0, and FFs 8n00 and 8n02 in the block circuit 8n0.

The block circuit 800 includes the FF 8000, an FF 8001, the FF 8002, and an FF 8003, combinational circuits 8004 and 8007, and combinational circuits 8005 and 8008 that are logical Ors for scan testing, and Muxes 8006 and 8009.

In this embodiment, instead of the logical ORs, logical XORs or the like may be used, as the combinational circuits 8005 and 8008. The output from the FF 8000 is input to a side of the Mux 8006, the side being a side where the selection signal is 0, and the output from the Mux 8006 is input to the FF 8001. In the same manner, the output from the FF 8002 is input to a side of the Mux 8009, the side being a side where the selection signal is 0, and the output from the Mux 8009 is input to the FF 8003. The output from the FF 105 is also input to the Muxes 8006 and 8009 as a selection signal for the Muxes 8006 and 8009. The FF 8001 is connected to the combinational circuit 8004, and the FF 8003 is connected to the combinational circuit 8007. The configuration described above is the same as that of the logic circuit 3101 according to the third embodiment illustrated in FIG. 7.

In the logic circuit 4101 according to this embodiment, the signals output from the combinational circuit 8004 are bundled by the combinational circuit 8005, and the resultant signal is input to a side of an Mux 8109 in the next block circuit, the side being a side where the selection signal is 1. In the same manner, the signals output from the combinational circuit 8007 are bundled by the combinational circuit 8008, and the resultant signal is input to a side of an Mux 8106 in the next block circuit, the side being a side where the selection signal is 1.

In this embodiment, the output from the FF 8001 is thus input to an FF 8103 via the combinational circuit, and the output from the FF 8003 is input to an FF 8101 via the combinational circuit. In the same manner, the output from the FF 8101 is input to the FF 8003 via the combinational circuit, and the output from the FF 8103 is input to the FF 8001 via the combinational circuit.

The Mux 8106 corresponds to a first multiplexer to which a signal output from the fourth combinational circuit in the first logic circuit block is input, and the output of which is input to the second flip-flop in the second logic circuit block. The Mux 8109 corresponds to a second multiplexer to which the signal output from the third combinational circuit in the first logic circuit block is input, and the output of which is input to the fourth flip-flop in the second logic circuit block. The Mux 8009 corresponds to a third multiplexer that receives the signal output from the third combinational circuit in the second logic circuit block, and the output of which is input to the fourth flip-flop in the first logic circuit block. The Mux 8006 corresponds to a fourth multiplexer to which the signal output from the fourth combinational circuit in the second logic circuit block is input, and the output of which is input to the second flip-flop in the first logic circuit block.

Because the FFs outputting the data are different from the FFs receiving the input of data, the data is more likely to change. As a result, the efficiency of the scan test analysis in the logic circuit 4101 is improved, and the effect of reducing the testing time can be achieved.

Furthermore, according to this embodiment, it is not necessary to provide an additional observation FF in the logic circuit 4101, as in the logic circuit 101 described above. Therefore, the number of scan shifts is reduced, so that the time required in the test is reduced, and the concerns about an increase in the area by the footprint occupied by the observation FF and an increase in the leakage power are eliminated. In this embodiment, the Muxes may be other combinational circuits or complex gate circuits.

### Fifth Embodiment

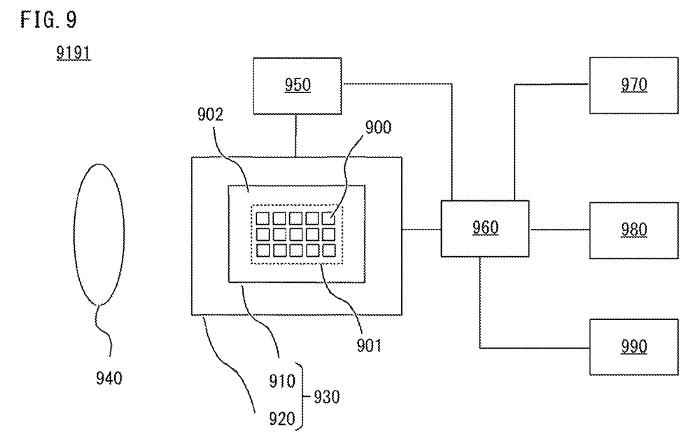

A semiconductor apparatus according to a fifth embodiment will now be explained. Any of the first to fourth embodiments described above can be applied to the semiconductor apparatus according to the fifth embodiment. FIG. 9 is a schematic view for describing equipment 9191 including a semiconductor apparatus 930 of the present embodiment. The equipment 9191 including the semiconductor apparatus 930 will be described in detail. The semiconductor apparatus 930 can include a semiconductor device 910 having a semiconductor layer 10, and a package 920 which houses the semiconductor device 910. The package 920 can include a substrate to which the semiconductor device 910 is fixed, and a lid made of glass or the like which faces the semiconductor device 910. The package 920 can further include a joining member such as a bonding wire or a bump which connects a terminal provided on the substrate and a terminal provided on the semiconductor device 910.

The equipment 9191 can include at least any of an optical device 940, a control device 950, a processing device 960, a display device 970, a storage device 980, and a mechanical device 990. The optical device 940 is compliant with the semiconductor apparatus 930. The optical device 940 is, e.g., a lens, a shutter, or a mirror. The control device 950 controls the semiconductor apparatus 930. The control device 950 is a semiconductor apparatus such as, e.g., an ASIC.

The processing device 960 processes a signal output from the semiconductor apparatus 930. The processing device 960 is a semiconductor apparatus such as a CPU or an ASIC for constituting an AFE (analog front end) or a DFE (digital front end). The display device 970 is an EL display device or a liquid crystal display device which displays information (image) obtained by the semiconductor apparatus 930. The storage device 980 is a magnetic device or a semiconductor device which stores information (image) obtained by the semiconductor apparatus 930. The storage device 980 is a volatile memory such as an SRAM or a DRAM, or a non-volatile memory such as a flash memory or a hard disk drive.

The mechanical device 990 has a moving unit or a propulsive unit such as a motor or an engine. In the equipment 9191, a signal output from the semiconductor apparatus 930 is displayed in the display device 970, and is transmitted to the outside by a communication device (not shown) provided in the equipment 9191. In order to do so, it is preferable that the equipment 9191 further includes the storage device 980 and the processing device 960 in addition to a storage circuit and an operation circuit of the semiconductor apparatus 930. The mechanical device 990 may also be controlled on the basis of a signal output from the semiconductor apparatus 930.

In addition, the equipment 9191 is suitably used as electronic equipment such as an information terminal having photographing function (e.g., a smartphone or a wearable terminal) or a camera (e.g., an interchangeable-lens camera, a compact camera, a video camera, or a surveillance camera). The mechanical device 990 in the camera can drive components of the optical device 940 for zooming, focusing, and shutter operation. Alternatively, the mechanical device 990 in the camera can move the semiconductor apparatus 930 for vibration isolation operation.

The equipment 9191 can be transport equipment such as a vehicle, a ship, or a flight vehicle. The mechanical device 990 in the transport equipment can be used as a moving device. The equipment 9191 serving as the transport equipment is suitably used as equipment which transports the semiconductor apparatus 930, or performs assistance and/or automation of driving (manipulation) with photographing function. The processing device 960 for assistance and/or automation of driving (manipulation) can perform processing for operating the mechanical device 990 serving as the moving device based on information obtained in the semiconductor apparatus 930. Alternatively, the equipment 9191 may also be medical equipment such as an endoscope, measurement equipment such as a distance measurement sensor, analysis equipment such as an electron microscope, office equipment such as a copier, or industrial equipment such as a robot.

According to the third embodiment as described above, it becomes possible to obtain excellent pixel characteristics. Consequently, it is possible to enhance the value of the semiconductor apparatus 930. At least any of addition of function, an improvement in performance, an improvement in characteristics, an improvement in reliability, an improvement in product yield, a reduction in environmental load, a reduction in cost, a reduction in size, and a reduction in weight corresponds to the enhancement of the value thereof mentioned herein.

Consequently, if the semiconductor apparatus 930 according to the third embodiment is used in the equipment 9191, it is possible to improve the value of the equipment as well. For example, when the semiconductor apparatus 930 is mounted on transport equipment and photographing of the outside of the transport equipment or measurement of an external environment is performed, it is possible to obtain excellent performance. Therefore, when the transport equipment is manufactured and sold, it is advantageous to determine that the semiconductor apparatus 930 according to the third embodiment is mounted on the transport equipment in terms of increasing the performance of the transport equipment itself. The semiconductor apparatus 930 is suitably used particularly as the transport equipment which performs driving assistance and/or automated driving of the transport equipment by using information obtained by the semiconductor apparatus 930.

Respective embodiments described up to this point, can be appropriately changed within the scope not departing from the technical idea. Incidentally, the contents disclosed in the present specification includes not only the description in the present specification but also all the matters comprehensible from the present specification and the drawings appended in the present specification. Further, the disclosed contents of the present specification include the complement of the concept described in the present specification. Namely, it can be said as follows: a description in the present specification to the effect that “A is larger than B” discloses to the effect that “A is not larger than B” even when the description to the effect that “A is not larger than B” is omitted. This is because it is a premise that the case where there is a description to the effect that “A is larger than B” is accomplished in consideration of the case where “A is not larger than B”.

According to the present disclosure, by returning the signal to the FF using the combinational circuit, a fault in the part connected to the analog circuit can be detected in a scan test. Furthermore, there is no concern about an increase in the circuit area and an increase in the number of scan shifts due to the addition of the observation FF. Furthermore, because the number of iterations of shift and capture operations in the scan test is reduced, the time and costs accrued in the tests can be reduced, advantageously.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-178727, filed on October 11, 2024 which is hereby incorporated by reference herein in its entirety.

What is claimed is:

1. A scan test circuit comprising:
a logic circuit; and
an analog circuit, wherein
the logic circuit includes a selection circuit and a plurality of logic circuit blocks to which a selection signal of the selection circuit is input,
each of the plurality of logic circuit blocks includes a first flip-flop, a second flip-flop, a third flip-flop, a fourth flip-flop, a first combinational circuit, and a second combinational circuit, and is caused to operate in response to an input of the selection signal of the selection circuit,
the selection circuit is connected to the first flip-flop and the third flip-flop,
the first flip-flop is connected to the second flip-flop,
the third flip-flop is connected to the fourth flip-flop,
the second flip-flop is connected to the first combinational circuit,
the first combinational circuit is connected to the analog circuit via a plurality of signal lines,
the plurality of signal lines connected to the first combinational circuit are connected to a third combinational circuit,
the fourth flip-flop is connected to the second combinational circuit,
the second combinational circuit is connected to the analog circuit via a plurality of signal lines,
the plurality of signal lines connected to the second combinational circuit are connected to a fourth combinational circuit,
the third combinational circuit is connected to the fourth flip-flop, and
the fourth combinational circuit is connected to the third flip-flop.

2. The scan test circuit according to claim 1, wherein, in a first logic circuit block and a second logic circuit block that are adjacent to each other, among the plurality of logic circuit blocks,
the third combinational circuit in the first logic circuit block is connected to the fourth flip-flop in the second logic circuit block, and
the fourth combinational circuit in the first logic circuit block is connected to the second flip-flop in the second logic circuit block.

3. The scan test circuit according to claim 1, wherein, in a first logic circuit block and a second logic circuit block that are adjacent to each other, among the plurality of logic circuit blocks,
the third combinational circuit in the second logic circuit block is connected to the fourth flip-flop in the first logic circuit block, and
the fourth combinational circuit in the second logic circuit block is connected to the second flip-flop in the first logic circuit block.

4. The scan test circuit according to claim 1, further comprising:
a first multiplexer to which a signal output from the fourth combinational circuit is input, and the output of which is input to the second flip-flop;
a second multiplexer to which a signal output from the third combinational circuit is input, and the output of which is input to the fourth flip-flop; and
a flip-flop that implements switching between the first multiplexer and the second multiplexer.

5. The scan test circuit according to claim 2, further comprising:
a first multiplexer to which a signal output from the fourth combinational circuit in the first logic circuit block is input, and the output of which is input to the second flip-flop in the second logic circuit block;
a second multiplexer to which a signal output from the third combinational circuit in the first logic circuit block is input, and the output of which is input to the fourth flip-flop in the second logic circuit block; and
a flip-flop that implements switching between the first multiplexer and the second multiplexer.

6. The scan test circuit according to claim 3, further comprising:
a first multiplexer to which a signal output from the fourth combinational circuit in the first logic circuit block is input, and the output of which is input to the second flip-flop in the second logic circuit block;
a second multiplexer to which a signal output from the third combinational circuit in the first logic circuit block is input, and the output of which is input to the fourth flip-flop in the second logic circuit block; and
a flip-flop that implements switching between the first multiplexer and the second multiplexer.

7. The scan test circuit according to claim 5, further comprising:
a third multiplexer to which a signal output from the third combinational circuit in the second logic circuit block is input, and the output of which is input to the fourth flip-flop in the first logic circuit block; and
a fourth multiplexer to which a signal output from the fourth combinational circuit in the second logic circuit block is input, and the output of which is input to the second flip-flop in the first logic circuit block, wherein
the flip-flop implements switching between the third multiplexer and the fourth multiplexer.

8. The scan test circuit according to claim 6, further comprising:
a third multiplexer to which a signal output from the third combinational circuit in the second logic circuit block is input, and the output of which is input to the fourth flip-flop in the first logic circuit block; and
a fourth multiplexer to which a signal output from the fourth combinational circuit in the second logic circuit block is input, and the output of which is input to the second flip-flop in the first logic circuit block, wherein
the flip-flop implements switching between the third multiplexer and the fourth multiplexer.

9. A photoelectric conversion device comprising:
a plurality of pixels arranged in a plurality of rows and a plurality of columns; and
a vertical scanning circuit that scans the plurality of pixels in a unit of one row, wherein
the vertical scanning circuit includes the scan test circuit according to claim 1.

10. A photoelectric conversion device comprising:
a plurality of pixels arranged in a plurality of rows and a plurality of columns;
a plurality of column circuits arranged correspondingly to the plurality of respective columns; and
a horizontal scanning circuit that scans the plurality of column circuits in a unit of one column, wherein
the horizontal scanning circuit includes the scan test circuit according to claim 1.

11. Equipment comprising a semiconductor device including the scan test circuit according to claim 1, the equipment further comprising at least any of:
an optical device corresponding to the semiconductor device;
a control device that controls the semiconductor device;
a signal processing device that processes a signal output from the semiconductor device;
a display device that displays information obtained by the semiconductor device;
a storage device that stores information obtained by the semiconductor device; and
a mechanical device that operates based on information obtained in the semiconductor device.
